(19) United States
(12) Patent Application Publication
(10) Pub. No.: US 2020/0264730 A1
(43) Pub. Date: Aug. 20, 2020

(54) SUBSTRATE FOR TOUCH SCREEN PANEL, TOUCH SCREEN PANEL HAVING SAME AND MANUFACTURING METHOD THEREOF

(71) Applicant: AMOGREENTECH CO., LTD., Gimpo-si, Gyeonggi-do (KR)

(72) Inventor: Sung-Baek DAN, Hwaseong-si, Gyeonggi-do (KR)

(21) Appl. No.: 16/646,924

(22) PCT Filed: Sep. 13, 2018
(86) PCT No.: PCT/KR2018/010773

§ 371 Date: Mar. 12, 2020

(30) Foreign Application Priority Data
Sep. 18, 2017 (KR) 10-2017-0119788

(51) Int. Cl. G06F 3/044; G03F 7/20

(52) U.S. Cl. CPC G06F 3/0445; G06F 2203/04103; G03F 7/2043

(57) ABSTRACT

Disclosed is a method for manufacturing a substrate for a touch screen panel in which a signal line pattern having a fine line width may be formed by forming a thin film deposition in a bezel region of a transparent substrate and forming a photoresist layer on a thin film deposition layer through an electrospinning process. The disclosed method for manufacturing a substrate for a touch screen panel comprises the steps of: preparing a plate-shaped transparent substrate having a sensing region and a bezel region located on the outer periphery of the sensing region; forming a transparent electrode layer in the sensing region of the transparent substrate; forming a thin film deposition layer in the bezel region of the transparent substrate; and forming a photoresist layer on an upper surface of the thin film deposition layer through an electrospinning process.

### TECHNICAL FIELD

The present disclosure relates to a touch screen panel, which senses a user's touch, mounted to an electronic device, and more particularly, to a substrate for a touch screen panel, a touch screen panel having the same, and a manufacturing method thereof, which minimizes the line width of a circuit pattern formed in the bezel region in order to implement bezeless, thereby minimizing the width of the bezel region.

### BACKGROUND ART

Recently, as the use of multimedia contents using portable terminals such as a smart phone and a tablet increases, the spread of portable terminals which provide a large screen is increasing.

As the portable terminal, a touch screen panel used as an input device is applied. The touch screen panel includes a touch sensing region and a bezel region.

The touch sensing region is formed with a touch circuit for touch sensing. Since the touch sensing region is needed to transmit a display screen while sensing the touch, the touch sensing region is made of a transparent material such as Indium Tin Oxide (ITO).

The bezel region is formed with a signal line pattern which transmits a signal sensed in the touch sensing region. Since the signal line pattern is made of a high conductive metal material, the bezel region blocks a portion (outer periphery) of the display screen.

Accordingly, in order to maximize the screen size while minimizing the increase in size, the portable terminal is applied with a touch screen panel which minimizes the width of the bezel region (that is, bezeless).

### DISCLOSURE

### Technical Problem

The present disclosure is proposed in consideration of the above point, and an object of the present disclosure is to provide a substrate for a touch screen panel and a manufacturing method thereof, which may form a thin film deposition layer on a bezel region of a transparent substrate, and form a signal line pattern having a fine line width by forming a photoresist layer on a thin film deposition layer through an electrospinning process.

In addition, another object of the present disclosure is to provide a substrate for a touch screen panel and a manufacturing method thereof, which form a signal line pattern having a fine line width by using a substrate for a touch screen panel, thereby minimizing the width of the bezel region.

### Technical Solution

For achieving the objects, a method for manufacturing a substrate for a touch screen panel according to an embodiment of the present disclosure includes preparing a plate-shaped transparent substrate having a sensing region and a bezel region located on the outer periphery of the sensing region, forming a transparent electrode layer in the sensing region of the transparent substrate, forming a thin film deposition layer in the bezel region of the transparent substrate, and forming a photoresist layer on the upper surface of the thin film deposition layer through an electrospinning process.

For achieving the objects, a substrate for a touch screen panel according to an embodiment of the present disclosure includes a plate-shaped transparent substrate having a sensing region and a bezel region located on the outer periphery of the sensing region, a transparent electrode layer formed on the upper surface of the sensing region, a thin film deposition layer formed on the upper surface of the bezel region, and a photoresist layer formed on the upper surface of the thin film deposition layer.

For achieving the objects, a method for manufacturing a touch screen panel according to an embodiment of the present disclosure includes preparing a base substrate which includes a transparent electrode layer formed in a sensing region, and a thin film deposition layer formed in a bezel region, and forming circuit patterns including a signal line pattern and a touch sensing circuit pattern by etching the transparent electrode layer and the thin film deposition layer.

At this time, the preparing of the base substrate may prepare the base substrate which includes a photoresist layer formed on the upper surface of the thin film deposition layer, and the forming of the circuit pattern may include forming a first mask by exposing and developing the photoresist layer, forming the signal line pattern by etching the thin film deposition layer by using the first mask as a barrier, forming a second mask in the sensing region of the base substrate, and forming the touch sensing circuit pattern by etching the transparent electrode layer by using the first mask as a barrier.

The preparing of the base substrate may prepare the base substrate which includes a photoresist layer formed on the upper surfaces of the transparent electrode layer and the thin film deposition layer, the forming of the circuit pattern may include forming a mask by exposing and developing the photoresist layer, forming the touch sensing circuit pattern in the sensing region by etching the transparent electrode layer by using the mask as a barrier, and forming the signal line pattern in the bezel region by etching the thin film deposition layer by using the mask as a barrier, and the forming of the touch sensing circuit pattern and the forming of the signal line pattern may be simultaneously performed.

For achieving the objects, a touch screen panel according to an embodiment of the present disclosure includes a plate-shaped transparent substrate having a sensing region and a bezel region located on the outer periphery of the sensing region, a touch sensing circuit pattern formed on the upper surface of the sensing region, and a signal line pattern formed on the upper surface of the bezel region. The signal line pattern may include an adhesive layer formed on the upper surface of the bezel region, a metal layer formed on the upper surface of the adhesive layer, and a protective layer formed on the upper surface of the metal layer, and the line width of the signal line pattern may be 10 nm or less.

### Advantageous Effects

According to the present disclosure, the substrate for the touch screen panel and the manufacturing method thereof may form the signal line pattern having the fine line width by forming the thin film deposition layer in the bezel region of the transparent substrate, and forming the photoresist layer on the thin film deposition layer through the electrospinning process.

In addition, the substrate for the touch screen panel and the manufacturing method thereof may form the signal line pattern having the fine line width by using the substrate for the touch screen panel, thereby minimizing the width of the bezel region.

### DESCRIPTION OF DRAWINGS

FIG. 1 is a diagram for explaining a touch screen panel.

FIG. 2 is a diagram for explaining a substrate for the touch screen panel according to an embodiment of the present disclosure.

FIG. 3 is a diagram for explaining a transparent substrate of FIG. 2.

FIG. 4 is a diagram for explaining a thin film deposition layer of FIG. 2.

FIG. 5 is a diagram for explaining a photoresist layer of FIG. 2.

FIGS. 6 and 7 are diagrams for explaining a method for manufacturing the substrate for the touch screen panel according to an embodiment of the present disclosure.

FIGS. 8 and 9 are diagrams for explaining forming a thin film deposition layer of FIG. 6.

FIG. 10 is a diagram for explaining forming a photoresist layer of FIG. 8.

FIGS. 11 and 12 are diagrams for explaining the touch screen panel according to an embodiment of the present disclosure.

FIGS. 13 and 14 are diagrams for explaining a method for manufacturing the touch screen panel according to an embodiment of the present disclosure.

FIGS. 15 and 16 are diagrams for explaining a method for manufacturing a touch screen panel according to another embodiment of the present disclosure.

### BEST MODE

Hereinafter, the most preferred embodiment of the present disclosure will be described with reference to the accompanying drawings in order to specifically describe so that those skilled in the art to which the present disclosure pertains may easily practice the technical spirit of the present disclosure. First, in adding reference numerals to the components of each drawing, it should be noted that the same components are denoted by the same reference numerals as much as possible even if displayed on different drawings. In addition, in describing the present disclosure, when it is determined that the detailed description of the related known configuration or function may obscure the gist of the present disclosure, the detailed description thereof will be omitted.

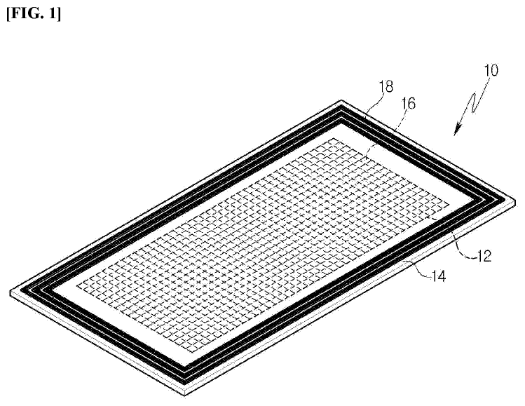

Referring to FIG. 1, a general touch screen panel 10 is classified into a sensing region 12 and a bezel region 14 which senses a touch.

The sensing region 12 is formed with a transparent electrode 16 (that is, a touch sensing circuit pattern) to provide light transmission while sensing the touch. The transparent electrode 16 is, for example, made of a transparent material such as ITO.

The bezel region 14 is a region disposed on the outer periphery of the sensing region 12. The bezel region 14 is formed with a signal line pattern 18 which transmits a signal sensed by the transparent electrode 16. The signal line pattern 18 may be formed through an Ag paste printing process and an exposure process. The signal line pattern 18 may also be formed through a laser patterning process.

In order to manufacture the bezeless touch screen panel 10, the signal line pattern 18 may be preferably formed to have the line width of about 10 nm or less.

However, since the signal line pattern 18 in the general touch screen panel 10 is formed by the paste printing and exposure or laser patterning process, the signal line pattern 18 has the line width of about 20 μm to about 30 μm.

Accordingly, an embodiment of the present disclosure provides a substrate for a touch screen panel, the touch screen panel having the same, and a manufacturing method thereof, which may form the signal line pattern having the line width of 10 μm or less.

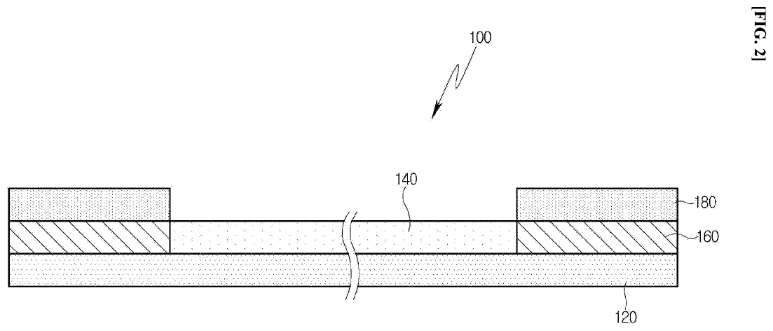

Referring to FIG. 2, the substrate for the touch screen panel 100 includes a transparent substrate 120, a transparent electrode layer 140, a thin film deposition layer 160, and a photoresist layer 180.

The transparent substrate 120 is formed of a plate-shaped substrate or a film. The transparent substrate 120 is made of a transparent material having light transmission in order to provide visibility of the display. For example, the transparent substrate 120 is COP or PET mainly used in the touch screen panel.

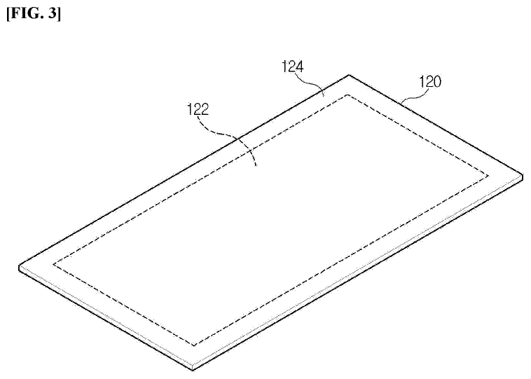

Referring to FIG. 3, the transparent substrate 120 includes a sensing region 122. The sensing region 122 is a region where transparent electrodes for touch sensing are formed.

The transparent substrate 120 further includes a bezel region 124 located outside the sensing region 122. The bezel region 124 is a region where the signal line pattern for transmitting signals sensed by the transparent electrodes of the sensing region 122 is formed.

The transparent electrode layer 140 is formed on at least one surface of the upper surface and the lower surface of the transparent substrate 120. The transparent electrode layer 140 is formed in the sensing region 122 of the transparent substrate 120. The transparent electrode layer 140 is a layer which forms the transparent electrode (that is, the touch sensing circuit pattern), and is an ITO, for example.

The thin film deposition layer 160 is formed on at least one surface of the upper surface and the lower surface of the transparent substrate 120. For example, the thin film deposition layer 160 is formed on the same surface as the transparent electrode layer 140.

The thin film deposition layer 160 is formed in the bezel region 124 of the transparent substrate 120 through a sputtering process. The thin film deposition layer 160 may be formed to have the thickness of about 200 mm to about 300 mm.

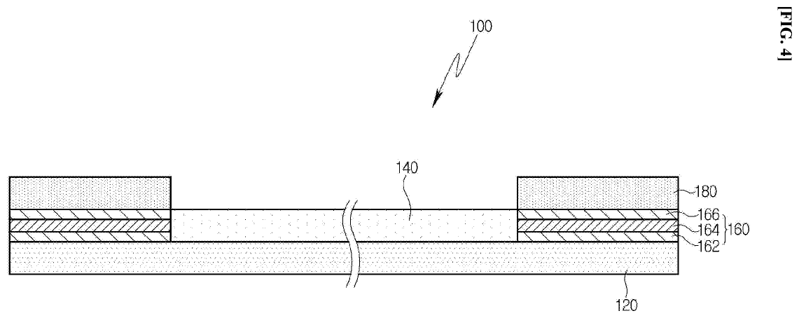

Referring to FIG. 4, the thin film deposition layer 160 may also be formed in a stacked structure in which an adhesive layer 162, a metal layer 164, and a protective layer 166 are stacked.

The adhesive layer 162 is formed on the surface of the transparent substrate 120. The adhesive layer 162 is formed in the bezel region 124 of the transparent substrate 120 through the sputtering process. The adhesive layer 162 may be, for example, one of nickel-copper (NiCu) and titanium (Ti).

The metal layer 164 is formed on the upper surface of the adhesive layer 162. The metal layer 164 is formed on the upper surface of the adhesive layer 162 through the sputtering process. The metal layer 164 is copper (Cu), for example.

The protective layer 166 is formed on the upper surface of the metal layer 164. The protective layer 166 is formed on the upper surface of the metal layer 164 through the sputtering process. The protective layer 166 is, for example, one of nickel-copper (NiCu) and titanium (Ti).

The photoresist layer 180 is formed on the surface of the thin film deposition layer 160. The photoresist layer 180 may be formed to have the thickness of about 3 μm to about 5 μm, for example.

The photoresist layer 180 is formed on the surface of the thin film deposition layer 160 through an electrospinning process. The photoresist layer 180 having the thickness of about 3 μm to about 5 μm is, for example, formed on the surface of the thin film deposition layer 160 by electrospinning the photoresist liquid (photosensitive polymer solution).

The photoresist layer 180 may also be formed on the surface of the thin film deposition layer 160 through a coating process. The photoresist layer 180 may be, for example, formed by coating the photoresist liquid on the surface of the thin film deposition layer 160 through one process of micro coating, casting, spin coating, slit coating, and die coating.

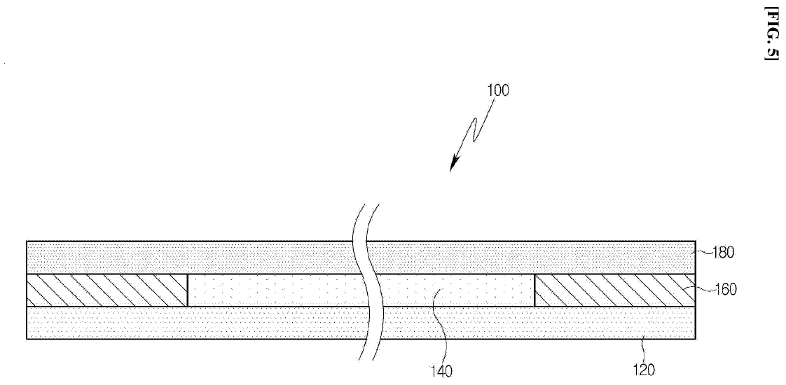

Referring to FIG. 5, the photoresist layer 180 may also be further formed in the sensing region 122 of the transparent substrate 120. The photoresist layer 180 is formed in the sensing region 122 and the bezel region 124 of the transparent substrate 120. The photoresist layer 180 is formed on the surface of the transparent electrode layer 140 in the sensing region 122, and is formed on the surface of the thin film deposition layer 160 in the bezel region 124.

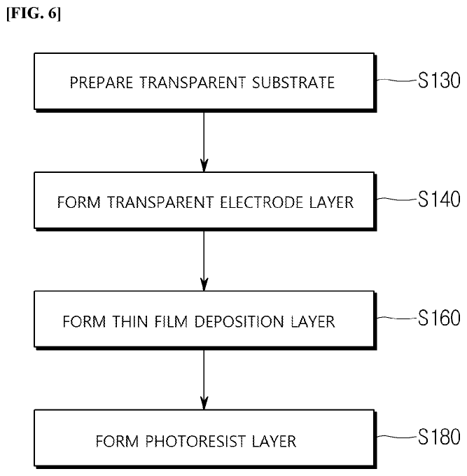

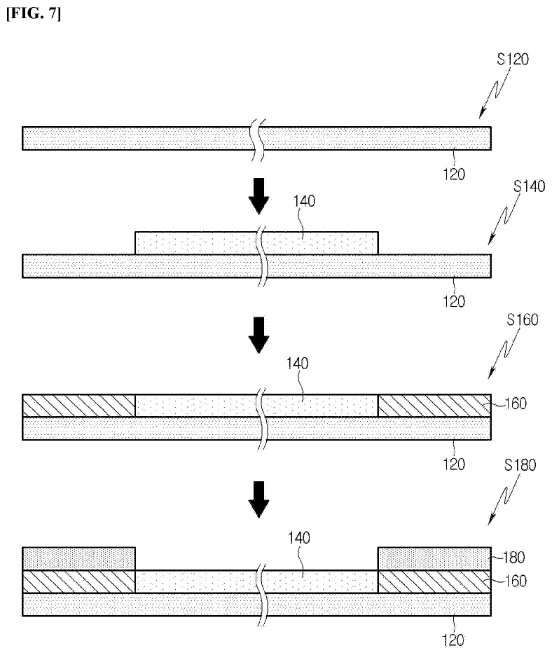

Referring to FIGS. 6 and 7, a method for manufacturing the substrate for the touch screen panel according to an embodiment of the present disclosure includes preparing a transparent substrate (S120), forming a transparent electrode layer (S140), forming a thin film deposition layer (S160), and forming a photoresist layer (S180).

The preparing of the transparent substrate (S120) prepares the transparent substrate 120 having light transmission. The preparing of the transparent substrate (S120) prepares the transparent substrate 120 having a plate-shaped substrate or a film form. The preparing of the transparent substrate (S120) prepares, as the transparent substrate 120, the plate-shaped substrate or the film of a COF or PET material mainly used for the touch screen panel, for example.

The preparing of the transparent substrate (S120) prepares the transparent substrate 120 including the sensing region 122 and the bezel region 124. The sensing region 122 is a region where transparent electrodes for touch sensing are formed. The bezel region 124 is located outside the sensing region 122.

The preparing of the transparent substrate (S120) may also prepare, as the transparent substrate 120, the stacked substrate or the stacked film where the transparent electrode layer 140 is formed in the sensing region 122. In this case, the forming of the transparent electrode layer (S140) to be described later may be omitted.

The forming of the transparent electrode layer (S140) forms the transparent electrode layer 140 on at least one surface of the upper surface and the lower surface of the transparent substrate 120. The transparent electrode layer 140 is formed in the sensing region 122 of the transparent substrate 120. The transparent electrode layer 140 is a layer which forms the transparent electrode, and is an ITO, for example.

The forming of the thin film deposition layer (S160) forms the thin film deposition layer 160 on the transparent substrate 120. The forming of the thin film deposition layer (S160) forms the thin film deposition layer 160 on at least one surface of the upper surface and the lower surface of the transparent substrate 120. The forming of the thin film deposition layer (S160) forms the thin film deposition layer 160 on the same surface as the transparent electrode layer 140, for example.

The forming of the thin film deposition layer (S160) forms the thin film deposition layer 160 in the bezel region 124 of the transparent substrate 120 through a sputtering process. The forming of the thin film deposition layer (S160) forms the thin film deposition layer 160 having the thickness of about 200 mm to about 300 mm.

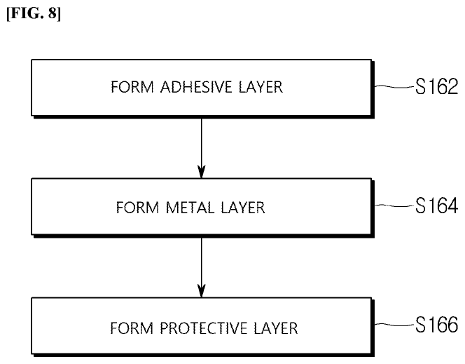

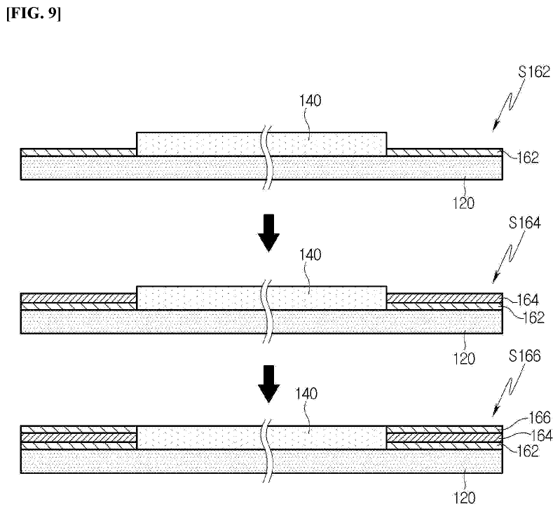

Referring to FIGS. 8 and 9, the forming of the thin film deposition layer (S160) may include forming an adhesive layer (S162), forming a metal layer (S164), and forming a protective layer (S166).

The forming of the adhesive layer (S162) forms the adhesive layer 162 on the surface of the transparent substrate 120. The forming of the adhesive layer (S162) forms the adhesive layer 162 in the bezel region 124 of the transparent substrate 120.

The forming of the adhesive layer (S162) forms the adhesive layer 162 on the surface of the transparent substrate 120 through a sputtering process. The forming of the adhesive layer (S162) forms the adhesive layer 162, which is one material of nickel-copper (Ni—Cu) and titanium (Ti), on the transparent substrate 120.

The forming of the metal layer (S164) forms the metal layer 164 on the upper surface of the adhesive layer 162. The forming of the metal layer (S164) forms the metal layer 164 on the upper surface of the adhesive layer 162 through a sputtering process. The forming of the metal layer (S164) forms the metal layer 164 made of copper (Cu) material on the upper surface of the adhesive layer 162, for example.

The forming of the protective layer (S166) forms the protective layer 166 on the upper surface of the metal layer 164. The forming of the protective layer (S166) forms the protective layer 166 on the upper surface of the metal layer 164 through the sputtering process. The forming of the protective layer (S166) forms the protective layer 166, which is one material of nickel-copper (Ni—Cu) and titanium (Ti), on the metal layer 164.

The forming of the photoresist layer (S180) forms the photoresist layer 180 on the surface of the thin film deposition layer 160. The forming of the photoresist layer (S180) forms the photoresist layer 180 in the thickness of about 3 μm to about 5 μm.

The forming of the photoresist layer (S180) forms the photoresist layer 180 on the surface of the thin film deposition layer 160 through an electrospinning process. The forming of the photoresist layer (S180) forms the photoresist layer 180 having the thickness of about 3 μm to about 5 μm on the surface of the thin film deposition layer 160 by electrospinning the photoresist liquid (photosensitive polymer solution), for example.

The forming of the photoresist layer (S180) may also form the photoresist layer 180 on the surface of the thin film deposition layer 160 through a coating process. The coating process is, for example, one of micro coating, casting, spin coating, slit coating, and die coating.

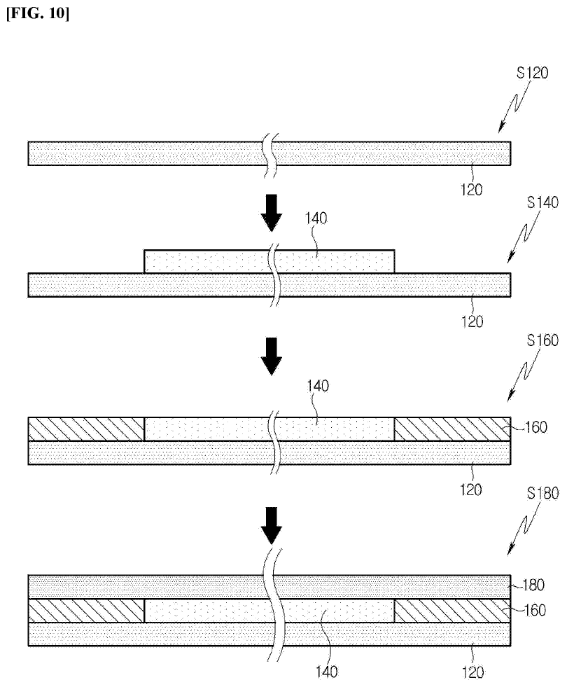

Referring to FIG. 10, the forming of the photoresist layer (S180) may further form the photoresist layer 180 in the sensing region 122 of the transparent substrate 120. The forming of the photoresist layer (S180) may form the photoresist layer 180 in the sensing region 122 and the bezel region 124 of the transparent substrate 120. The photoresist layer 180 is formed on the surface of the transparent electrode layer 140 in the sensing region 122, and is formed on the surface of the thin film deposition layer 160 in the bezel region 124.

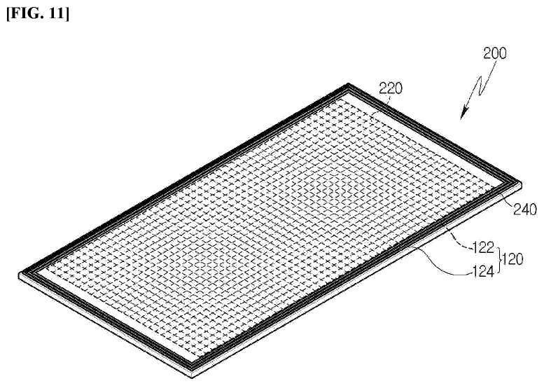

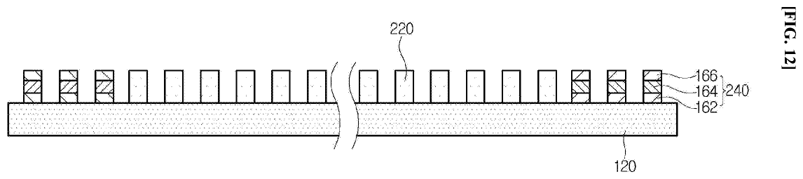

Referring to FIGS. 11 and 12, a touch screen panel 200 according to an embodiment of the present disclosure includes the transparent substrate 120, a touch sensing circuit pattern 220, and a signal line pattern 240.

The transparent substrate 120 is formed of a plate-shaped substrate or a film. The transparent substrate 120 is made of a transparent material having light transmission in order to provide visibility of the display. The transparent substrate 120 is, for example, COP or PET mainly used for the touch screen panel 200.

The transparent substrate 120 includes the sensing region 122 and the bezel region 124. The sensing region 122 is a region where transparent electrodes for touch sensing are formed. The bezel region 124 is a region where the signal line pattern 240 which transmits signals sensed by the transparent electrodes of the sensing region 122 is formed.

The touch sensing circuit pattern 220 is formed in the sensing region 122 of the transparent substrate 120. The touch sensing circuit pattern 220 may include a plurality of X-axis sensing circuit patterns and a plurality of Y-axis sensing circuit patterns.

The touch sensing circuit pattern 220 is formed by etching the transparent electrode layer 140 of the substrate for the touch screen panel 100. The touch sensing circuit pattern 220 may be formed simultaneously with the signal line pattern 240 through an etching process.

The touch sensing circuit pattern 220 may also be formed through a separate etching process before and after forming the signal line pattern 240 by using the photoresist layer 180.

The signal line pattern 240 is formed in the bezel region 124 of the transparent substrate 120. The signal line pattern 240 has the thickness of about 200 mm to about 300 mm, and is formed to have the line width of about 10 μm or less.

The signal line pattern 240 may include an X-axis signal line pattern 240 which transmits a signal of the X-axis sensing circuit pattern and a Y-axis signal line pattern 240 which transmits a signal of the Y-axis sensing circuit pattern.

The signal line pattern 240 transmits a touch sensing signal generated by the touch sensing circuit pattern 220. The signal line pattern 240 transmits the sensing signal to the main circuit board of the portable terminal, for example.

The signal line pattern 240 is formed by etching the thin film deposition layer 160 and the photoresist layer 180 of the substrate for the touch screen panel 100. The signal line pattern 240 may be formed simultaneously with the touch sensing circuit pattern 220 through the etching process. The signal line pattern 240 may also be formed through a separate etching process before and after forming the touch sensing circuit pattern 220.

The signal line pattern 240 may include the adhesive layer 162, the metal layer 164, and the protective layer 166. The adhesive layer 162 is formed on the surface of the transparent substrate 120, and is, for example, one of nickel-copper (NiCu) and titanium (Ti). The metal layer 164 is formed on the upper surface of the adhesive layer 162, and is copper (Cu), for example. The protective layer 166 is formed on the upper surface of the metal layer 164, and is, for example, one of nickel-copper (NiCu) and titanium (Ti).

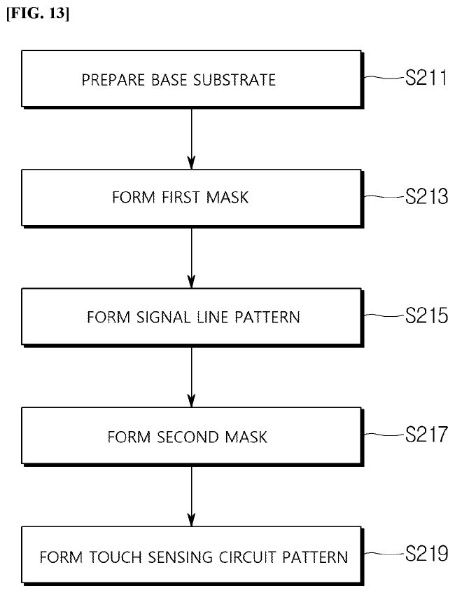

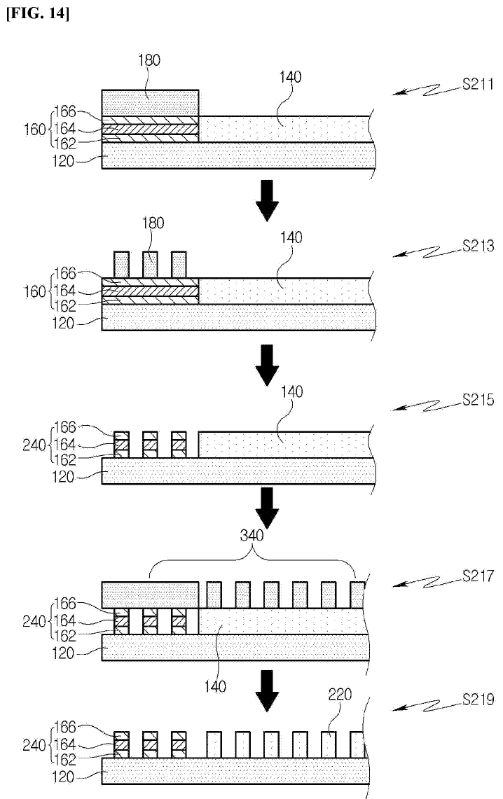

Referring to FIGS. 13 and 14, a method for manufacturing the touch screen panel 200 according to an embodiment of the present disclosure may include preparing a base substrate (S211), forming a first mask (S213), forming the signal line pattern (S215), forming a second mask (S217), and forming the touch sensing circuit pattern 220 (S219).

The preparing of the base substrate (S211) prepares the substrate for the touch screen panel 100 as the base substrate. The preparing of the base substrate (S211) prepares, as the base substrate, the substrate for the touch screen panel 100 where includes the thin film deposition layer 160 and the photoresist layer 180 formed only in the bezel region 124 of the transparent substrate 120.

The forming of the first mask (S213) forms a first mask 320 by exposing and developing the photoresist layer 180 of the substrate for the touch screen panel 100. The forming of the first mask (S213) forms the first mask 320 having a shape corresponding to the signal line pattern 240.

The forming of the signal line pattern (S215) forms the signal line pattern 240 having a fine line width by etching the thin film deposition layer 160. The forming of the signal line pattern (S215) etches the thin film deposition layer 160 by using the first mask 320 as a barrier. The forming of the signal line pattern (S215) forms the signal line pattern 240 having the line width of about 10 μm or less.

The forming of the second mask (S217) forms a second mask 340 on the upper surface of the transparent electrode layer 140 of the substrate for the touch screen panel 100. The forming of the second mask (S217) applies the photoresist liquid to the upper surface of the transparent electrode layer 140 through an electrospinning process or a coating process. The forming of the second mask (S217) forms the second mask 340 of the shape corresponding to the touch sensing circuit pattern 220 by exposing and developing the photoresist liquid. The forming of the second mask (S217) may also form the second mask 340 by adhering a dry film to the upper surface of the transparent electrode layer 140.

The forming of the touch sensing circuit pattern 220 (S219) forms the touch sensing circuit pattern 220 by etching the transparent electrode layer 140. The forming of the touch sensing circuit pattern 220 (S219) etches the transparent electrode layer 140 by using the second mask 340 as a barrier.

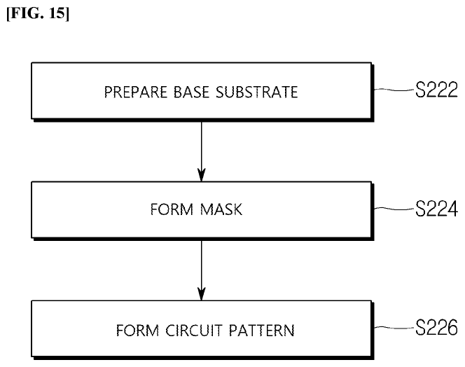

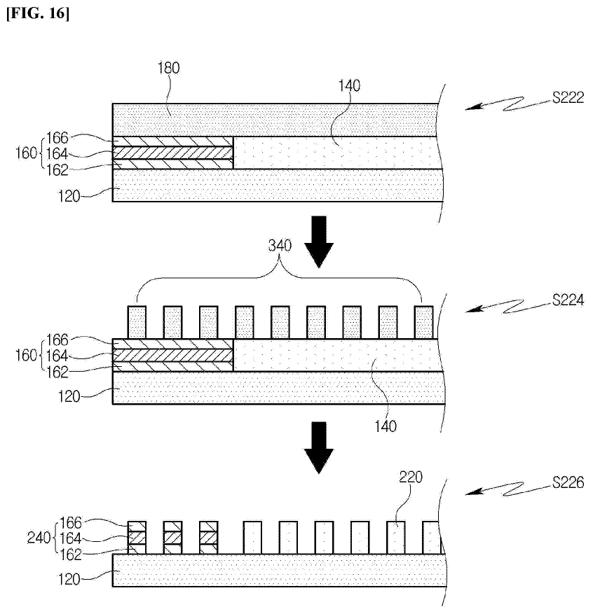

Referring to FIGS. 15 and 16, a method for manufacturing the touch screen panel 200 according to another embodiment of the present disclosure may include preparing a base substrate (S222), forming a mask (S224), and forming a circuit pattern (S226).

The preparing of the base substrate (S222) prepares the substrate for the touch screen panel 100 as the base substrate. The preparing of the base substrate (S222) prepares, as the base substrate, the substrate for the touch screen panel 100 which includes the photoresist layer 180 formed in the sensing region 122 and the bezel region 124 of the transparent substrate 120.

The forming of the mask (S224) forms a mask 300 by exposing and developing the photoresist layer 180 of the substrate for the touch screen panel 100. The forming of the mask (S224) forms the mask 300 having the shape corresponding to the signal line pattern 240 and the touch sensing circuit pattern 220. The forming of the mask (S224) forms the mask 300 having the shape corresponding to the touch sensing circuit pattern 220 on the photoresist layer 180 of the sensing region 122. The forming of the mask (S224) forms the mask 300 having the shape corresponding to the signal line pattern 240 on the photoresist layer 180 of the bezel region 124.

The forming of the circuit pattern (S226) forms the touch sensing circuit pattern 220 and the signal line pattern 240 by etching the substrate for the touch screen panel 100. The forming of the circuit pattern (S226) forms the touch sensing circuit pattern 220 by etching the transparent electrode layer 140 of the substrate for the touch screen panel 100. The forming of the circuit pattern (S226) forms the signal line pattern 240 by etching the thin film deposition layer 160 of the substrate for the touch screen panel 100.

While the preferred embodiment according to the present disclosure has been described above, modifications may be made in various forms, and it is understood that those skilled in the art will be able to practice various changes and modifications without departing from the claims of the present disclosure.

1. A method for manufacturing a substrate for a touch screen panel, the method comprising:
preparing a plate-shaped transparent substrate having a sensing region and a bezel region located on the outer periphery of the sensing region;
forming a transparent electrode layer in the sensing region of the transparent substrate;
forming a thin film deposition layer in the bezel region of the transparent substrate; and
forming a photoresist layer on the upper surface of the thin film deposition layer.

2. The method of claim 1,
wherein the transparent substrate is a COP or PET material, and the transparent electrode layer is an ITO material.

3. The method of claim 1,
wherein the forming of the thin film deposition layer comprises
forming an adhesive layer on the upper surface of the bezel region;
forming a metal layer on the upper surface of the adhesive layer; and
forming a protective layer on the upper surface of the metal layer.

4. The method of claim 1,
wherein the forming of the photoresist layer forms the photoresist layer through an electrospinning process.

5. The method of claim 1,
wherein the forming of the photoresist layer further forms the photoresist layer on the upper surface of the transparent electrode layer.

6.-7. (canceled)

8. The method of claim 3,
wherein the adhesive layer and the protective layer are one of nickel-copper (Ni—Cu) and titanium (Ti), and the metal layer is copper (Cu).

9. (canceled)

10. A method for manufacturing a touch screen panel, the method comprising:
preparing a base substrate which comprises a transparent electrode layer formed in a sensing region, and a thin film deposition layer formed in a bezel region; and
forming circuit patterns comprising a signal line pattern and a touch sensing circuit pattern by etching the transparent electrode layer and the thin film deposition layer.

11. The method of claim 10,
wherein the preparing of the base substrate prepares the base substrate which comprises a photoresist layer formed on the upper surface of the thin film deposition layer.

12. The method of claim 11,
wherein the forming of the circuit pattern comprises
forming a first mask by exposing and developing the photoresist layer;
forming the signal line pattern by etching the thin film deposition layer by using the first mask as a barrier;
forming a second mask in the sensing region of the base substrate; and
forming the touch sensing circuit pattern by etching the transparent electrode layer by using the first mask as a barrier.

13. The method of claim 10,
wherein the preparing of the base substrate prepares the base substrate which comprises a photoresist layer formed on the upper surfaces of the transparent electrode layer and the thin film deposition layer.

14. The method of claim 13,
wherein the forming of the circuit pattern comprises
forming a mask by exposing and developing the photoresist layer;
forming the touch sensing circuit pattern in the sensing region by etching the transparent electrode layer by using the mask as a barrier; and
forming the signal line pattern in the bezel region by etching the thin film deposition layer by using the mask as a barrier.

15. The method of claim 14,
wherein the forming of the touch sensing circuit pattern and the forming of the signal line pattern are simultaneously performed.

16. A touch screen panel comprising:
as the touch screen panel manufactured by the method for manufacturing the touch screen panel described in claim 10,
a plate-shaped transparent substrate having a sensing region and a bezel region located on the outer periphery of the sensing region;
a touch sensing circuit pattern formed on the upper surface of the sensing region; and
a signal line pattern formed on the upper surface of the bezel region.

17. The touch screen panel of claim 16,
wherein the signal line pattern comprises
an adhesive layer formed on the upper surface of the bezel region;
a metal layer formed on the upper surface of the adhesive layer; and
a protective layer formed on the upper surface of the metal layer.

18. The touch screen panel of claim 16,
wherein the line width of the signal line pattern is 10 μm or less.
